(19) United States
(12) Patent Application Publication
(10) Pub. No.: US 2024/0218587 A1
(43) Pub. Date: Jul. 4, 2024

(54) VAPOUR DEPOSITION PRODUCT AND METHOD THEREFOR

(71) Applicant: SURVIVON LTD, Eveleigh, New South Wales (AU)

(72) Inventors: Thomas HUSSEY, Drummoyne, New South Wales (AU); Chih Lung LIN, New Taipei City (TW); Shih-Yang CHEN, Taoyuan City (TW); Alessandra SUTTI, Geelong, Victoria (AU); Scott WHITBY, Chatswood, New South Wales (AU)

(21) Appl. No.: 18/558,508

(22) PCT Filed: May 2, 2022
(86) PCT No.: PCT/AU2022/050408

§ 371 Date: Nov. 1, 2023

(30) Foreign Application Priority Data
May 3, 2021 (AU) 2021901312
Jun. 2, 2021 (AU) 2021901649

(51) Int. Cl. D06M 10/06; D06M 11/42; D06M 11/83

(52) U.S. Cl. CPC D06M 10/06; D06M 11/42; D06M 11/83

(57) ABSTRACT

A substrate with a film. The substrate with a film comprising a porous substrate. The porous substrate having one or more pores extending through the substrate. A film can be applied to the porous substrate. The film being a vapour deposited film formed from a metal vapour adhering to the surface of the substrate, and wherein the film comprises a metal and a metal oxide.

### TECHNICAL FIELD

The present disclosure relates to a product with a film applied thereto and a method for producing said film. More particularly, the present disclosure may be directed towards a substrate with a vapour deposited film applied thereto and a method for manufacture.

### BACKGROUND

The process of applying a film to a substrate with a physical or chemical vapour deposition methods is well known. Chemical Vapour Deposition (CVD) methods involve a substrate in a vacuum being exposed to one or more volatile precursors, which react and/or decompose on the substrate surface to produce the desired deposit.

Similarly, a Physical Vapour Deposition (PVD) treatment involves a substrate in a vacuum in which a material to be coated onto the substrate is transitioned from a condensed phase to a vapor phase and then back to a thin film condensed phase. These films may be metal films and are generally applied to continuous non-porous substrates for use in food packaging, and window tinting, for example. Other applications may also be related to aerospace, automotive, and jewellery production applications.

Vapour deposition processes may impart a property to the substrate, such as improving hardness, wear resistance and oxidation resistance. These processes may be used in roll-to-roll systems or used to treat 3D articles within a vacuum vessel.

In addition, it has become desirable to apply a film to a substrate, particularly films which have one or more functional properties. Notably, it may be desired to impart an antibacterial or antimicrobial coating which may be utilised for a number of applications. This may be particularly useful for medical garments, medical applications, and general health applications. However, there are inherent difficulties applying durable coatings which may achieve these functions, and other difficulties associated with aesthetic application of these materials.

The present disclosure may offer a solution to the known problems within the art, or provide a suitable alternative.

Any discussion of the prior art throughout the specification should in no way be considered as an admission that such prior art is widely known or forms part of common general knowledge in the field.

### SUMMARY

### Problems to be Solved

It may be advantageous to provide for a substrate which has a film deposited thereon.

It may be advantageous to provide for a substrate which has a metal coating applied thereto.

It may be advantageous to provide for a method of controlling oxidation of a metal film.

It may be advantageous to provide a substrate with at least one functional coating applied thereto.

It may be advantageous to provide for a substrate with a metal film with a layer of oxidation.

It may be advantageous to provide for a film which is at least semi-transparent.

It may be advantageous to provide for a film which may be a high emissivity surface.

It is an object of the present invention to overcome or ameliorate at least one of the disadvantages of the prior art, or to provide a useful alternative.

### Means for Solving the Problem

A first aspect of the present invention may relate to a substrate with a film. The substrate may be a porous substrate and may comprise one or more pores extending through the substrate. A film may be applied to the porous substrate. The film may be a vapour deposited film formed from a metal vapour adhering to the surface of the substrate; and wherein the film may comprise a metal and/or a metal oxide.

Preferably, the metal oxide may be at least 5 nm in thickness. Preferably, the metal of the film may be at least 5 nm in thickness. Preferably, the tensile strength of the substrate may be in the range of 75% to 95% of the tensile strength relative to a substrate without a film. Preferably, the ΔE of the film may be less than 3 after a period of more than 4 hours of the film being applied, relative to the colour of the film at the time of initial exposure to atmosphere external a film deposition system. Preferably, the film is a copper film comprising a copper portion with a purity of greater than 95% and an oxide portion. Preferably, the emissivity of the film may be in the range of 0.1 to 0.8. Preferably, the substrate may be been exposed to a cooling process such that the ΔE of the film may not be greater than 3 after a period of 4 hours, relative to the film at the time of removal from a film deposition system. Preferably, the substrate may be selected from the group of; a non-woven substrate, a membrane, a woven substrate, a fabric, and a textile. Preferably, the substrate may be cooled to a temperature in the range of 100° C. to 0° C. to control the metal oxide thickness. Preferably, the thickness of the film may be in the range of 5 nm to 500 nm, and may comprise a metal layer and a metal oxide layer. Preferably, the substrate may have a first colour on a first side, and may have a second colour on a second side. Preferably, the film may have an emissivity of less than 0.15. Preferably, the film may have an emissivity of greater than 0.6. Preferably, the metal may be selected from the following group; aluminium, copper, zinc, gold, silver, titanium, chrome, and nickel.

In the context of the present invention, the words “comprise”, “comprising” and the like are to be construed in their inclusive, as opposed to their exclusive, sense, that is in the sense of “including, but not limited to”.

The invention is to be interpreted with reference to the at least one of the technical problems described or affiliated with the background art. The present aims to solve or ameliorate at least one of the technical problems and this may result in one or more advantageous effects as defined by this specification and described in detail with reference to the preferred embodiments of the present invention.

### BRIEF DESCRIPTION OF THE FIGURES

FIG. 1 illustrates a section view of a system which may be suitable for applying a film to a substrate;

FIG. 2 illustrates a perspective view of an embodiment of a roll which has had a film applied thereto;

FIG. 3 illustrates an embodiment of a section of a substrate with a film applied thereto with varying oxidation;

FIG. 4 illustrates another embodiment of a section of a substrate which comprises variable oxidation locations;

FIG. 5 illustrates a graph with FTIR analysis for a number of samples with varying oxidation;

FIG. 6 illustrates an example of an exposure graph for a substrate under different temperatures;

FIG. 7A illustrates an embodiment of a process flowchart for controlling the formation of oxidation;

FIG. 7B illustrates another embodiment of a process flowchart for controlling the formation of oxidation;

FIG. 8A illustrates a side view of an embodiment of a substrate with an oxide formed at the upper surface of a film; and

FIG. 8B illustrates a side view of another embodiment of a substrate with an oxide formed which penetrates through a majority of the film.

### DESCRIPTION OF THE INVENTION

Preferred embodiments of the invention will now be described with reference to the accompanying drawings and non-limiting examples.

### Features

1 System
2 Chamber
3 Deposition Chamber
4 Winding System
5 Roll
6 Cooling device
10 Substrate
11 Core
12 Centre Roll Portion
14 Middle Roll Portion
16 Outer Roll Portion
30 Film
40 Substrate Edge
45 Substrate Middle
50 Low emissivity section
55 High emissivity section
100 Method
105 Step 1
110 Step 2
115 Step 3
120 Step 4
125 Step 5
130 Step 6
135 Step 7
140 Step 8
145 Step 9
155 Upper portion
160 Lower portion

A vacuum processing system 1 is adapted for applying a film to a substrate 10. The system 1 can be used for at least one of a physical vapour deposition process and a chemical vapour deposition process. The system 1 may have plasma enhanced capabilities which may allow for a plasma treatment to be imparted to the substrate 10. The plasma treatment may be a pre-treatment or a post-treatment which is applied to the substrate. Pre-treatment with plasma may result in surface modification of the substrate 10 surface to improve adhesion of the film to be deposited on the substrate surface, or otherwise to improve the treatment. The substrate 10 morphology may also be improved which may allow for a superior film to be applied thereto. At least one chamber of the system may be a processing chamber such as a CVD chamber, PVD chamber, PECVD chamber, PEPVD chamber, etching chamber, plasma chamber, cooling chamber, drying chamber, or any other preferred processing chamber.

The plasma treatment may include the use of an inert gas for use as plasma fluid, such as argon, xenon, helium, neon, and krypton, or alternatively other plasma gases may be used such as oxygen or nitrogen, for example. It will be appreciated that the gas selected may be any suitable plasma gas, and may be used to impart a functionality to the substrate or otherwise activate the surface of the substrate. Plasma treatments may also be used to temporarily or permanently modify the surface functionality of the substrate, or film applied thereto, or may be used to alter an existing functionality temporarily.

The system may have one or more chambers which can be of different vacuum pressures. For example, the system 1 may have a first chamber where the substrate can be mounted, and a second chamber wherein a film can be applied to the substrate 10. Each chamber may have a respective predetermined pressure. Optionally, further chambers may also be provided which can be used to cool the substrate 10, apply a treatment to the substrate, or apply a second film or coating to the substrate 10.

In another embodiment, the system 1 may include at least one processing chamber which may accommodate processing components. In the present disclosure, a “processing component” may be at least one of the following: a component for depositing a material on a substrate, a component for heating a substrate, a component for cooling a substrate, a component for pre-treating a substrate, a component for etching a substrate, and component for cleaning the substrate. As such, the processing chamber of the system 1 may comprise a deposition source for depositing material on the substrate, a heating device, a cooling device, and a cleaning device. The process may include pre-treatment devices, etching devices, and the like. In another embodiment, a pre-treated plasma source can be provided for treating the substrate with plasma. The cooling device of the system 1 may be a cooling drum 6 or another device which may transport a substrate 10 during processing, or otherwise cool the substrate during processing.

The system 1 may include a roll-to-roll winding system, which can wind and unwind a fabric. The winding system may be reversable, such that the substrate mounted onto the winding system can unwind and/or rewind in either a first or second direction. Utilising a system with a winder and unwinder which may allow for winding in either direction allows the system to remain pressurised while processing is carried out. Notably, this is also useful to also allow for cooling of a substrate which may be of a temperature which exceeds a desired temperature.

The winding system may allow for a predetermined tension to be imparted to the substrate. The tension imparted may also assist with application of a film or deposition coating to the substrate 10 and may also assist with providing a suitable winding tension to accurately rewind.

A cooling drum can be used to cool a substrate 10 when inside the system 1. The cooling drum may be heated or cooled in the range of 30° C. to −30° C. The temperature change imparted by the drum can be used to reduce the temperature of the substrate 10 at a desired rate. The function of the cooling drum in typical use for the system is used to assist with condensation of vapour which is used to form the film on a substrate. However, the use of the drum in a subsequent process for cooling without applying a film is unknown in the art.

The cooling device 6 may be a cooling drum adapted to rotate about an axis which can assist with the transport of the substrate, while also distributing the heat from the substrate 10. The cooling drum may be adapted to operate at a first temperature during deposition treatment, and a second temperature during a cooling step. Each of these respective steps may impart a desired durability to the film deposited, or may impart a desired level or type of oxidation to a film applied to the substrate 10.

In a pre-treatment step the plasma treatment may be used to clean a substrate 10, or activate the surface of the substrate 10. The surface activation may allow for an improved adhesion of a film to a substrate 10, and may also reduce the potential for contaminants to remain on the surface of the substrate before a film is applied.

In yet a further embodiment, there is provided a method for manufacture of a product. The product having a predetermined film thickness and the film having a predetermined oxidation thereon. The oxidation may relate to the thickness of the oxidation layer, the oxides formed thereon or otherwise the colour of the film.

In one embodiment, the film may corrode to include copper oxide at a temperature greater than approximately 75° C., or copper hydroxide may be formed at a temperature around 50° C. other oxides can also be formed at different temperatures which may impact one or more functional properties of the coating.

Further, the conductivity of the of the substrate 10 may be impacted by the thickness of the oxide layer formed on the substrate. It is preferred that the oxide layer formed be a protective coating, while also leaving a minimum thickness of deposited material. For example, if the deposition is a copper film, the thickness of the copper layer without oxides is preferably at least 20 nm thick.

The thermal conductivity is also related to the thickness of the copper layer. Thicker copper films have a higher thermal conductivity to thinner films.

The thickness of the film may be one factor in assessing electrical conductivity, as defects, breaks or disruption of the film after wearing can reduce the potential for electrical conductivity. As such, if electrical conductivity is desired, the film is preferably processed in a way to reduce the oxidation.

From the heat of deposition, the substrate may reach a temperature in the range of between 90° C. to 250° C. This temperature may accelerate oxidation at the surface when the substrate is exposed to oxygen, which may be undesired. As such, the system 1 may be used to control the cooling of the substrate 10 in at least a partial vacuum such that the interaction with oxygen is limited and thereby the oxidation is also limited.

In another embodiment, the cooling process may impart a desired reflectivity to the substrate. Cooling the film may impart at least one desired type of oxide to the film. The films may be formed from any predetermined metal. In one example, if the metal is a copper at least one copper oxide may be formed. Copper oxide may refer to at least one of the following: Copper(I) oxide (cuprous oxide, Cu₂O), Copper (II) oxide (cupric oxide, CuO), Copper peroxide (CuO₂), Copper (III) oxide (Cu₂O₃), Copper (IV) oxide (CuO₂).

The visual change between two colours may be quantified by identifying two points in Lab colour space (CIELAB color space). The difference between the two points calculated is the Delta E (ΔE). The LAB colour space is designed to imitate human vision and distinguish the subtle differences between colours, or obvious differences between colours and quantify the difference between them.

It is preferred that a coating applied with the method results in a film which has a a ΔE<2 value with respect to a first colour and a second colour. It is preferred that the ΔE be less than around 3, as this is the range where most persons may distinguish a minor variation in colour change between two samples. However, in some circumstances it may be desirable to alter the ΔE greater than 3 to achieve a predetermined colour. The predetermined colour may then be compared against a benchmark sample colour and at this time the ΔE between the two samples is preferably <3, or more preferably is <2.

In one embodiment, the deposition is applied with a film which at the time of exposure to an oxidant, such as breathable atmosphere or oxygen is of a known colour, the known colour is preferably the benchmark colour, and discolouration of the substrate is relatively compared to the benchmark colour. The process may be adapted to allow for a ΔE of <3 (less than 3) in ideal conditions, and more preferably a ΔE of <2 (less than 2).

As the substrates are wound onto rolls the heat from the deposition, and any pre-treatments may be retained within the roll. Pre-treatments may include a heating process or a plasma process, for example, which can impart thermal energy to the substrate 10, and therefore increase the temperature of the substrate 10. Further, the process of evaporating metal and subsequent condensing of the metal onto the substrate also heats the substrate. For processing and applying a film to the substrate 10, the evaporation boats are heated to a temperature which allows for metal wire to melt and turn to vapour. The metal vapour then rises and condenses onto the substrate forming the film. During this time, the radiant heat from the boats may heat the substrate in addition to the metal condensing onto the substrate 10. To encourage a desired condensation, the system 1 may be fitted with a cooling drum 6 or rotary drum which assists with the deposition of film by encouraging condensation onto the substrate 10. Both CVD processes, such as sputtering processes, and PVD processes may heat the substrate 10, and the film applied thereto may also heat the substrate or retain heat.

While the cooling drum 6 is adapted to cool the substrate 10 to assist with condensation of the metal vapour onto the surface, the temperature of the substrate 10 will still be in an oxidation temperature range of between 50° C. to around 150° C. or greater. Further, as deposition occurs in a vacuum, there is little ability for heat to be transferred from the substrate 10 via conduction or convection to surrounding atmosphere, and as the substrate is wound onto the roll 5 the overall temperature of the roll 5 is maintained or increased with the addition of heated substrate 10. Further, if heat is lost via radiant energy from the roll 5, the sides and the outer surface of the roll will generally cool before the middle of the roll.

In this way the roll may have a relatively higher amount of resident heat within different sections of the roll compared to other sections. For example, if the core of the roll comprises a hollow core, the centre of the roll may be of a similar temperature as that of the outer portions of the roll. In this example, the temperature of the substrate between the centre and the outer portion will be of a relatively higher temperature. In another example, the core is supported by a conductive axis or a conductive support, the conductive axis or support may transfer heat from at least one section of the roll near to the core thereby cooling the substrate unevenly. Uneven cooling may not be advantageous as the middle of the roll 5 may be of a relatively higher temperature relative to the section of the roll 5 near to the core.

Preferably the substate may be a non-woven, a woven textile, or a porous substrate. Typically the treatments applied to substrates are for polymeric films, such as the materials for food packaging and other airtight products. As these products are continuous films, the substrates after winding generally have very little to no air within between the winding layers of the roll, and therefore oxidation is eliminated or minimised. However, for textiles or porous substrates oxidation of applied metal depositions can occur rapidly, unevenly and cause different oxidated materials to form throughout the roll, which can limit or remove any desired functionality or visual aesthetics.

Non-porous substrates generally do not let any air in between the film layers when the chamber is vented to atmosphere after deposition. This therefore allows the middle section of the rolls to cool before being exposed to air, and therefore oxidation is not possible.

However, in the case of porous materials, such as webbing, fabrics, nonwoven textiles and the like, air can permeate to sections of the roll which are of a relatively higher temperature which can allow oxidation to occur. Further, with increased temperatures, generally temperatures greater than around 50° C., the rate of oxidation or the depth of oxidation is increased when exposed to oxygen.

The method described within this specification outlines at least one method for limiting, controlling, or eliminating undesired oxidation of the substrate of the roll 5.

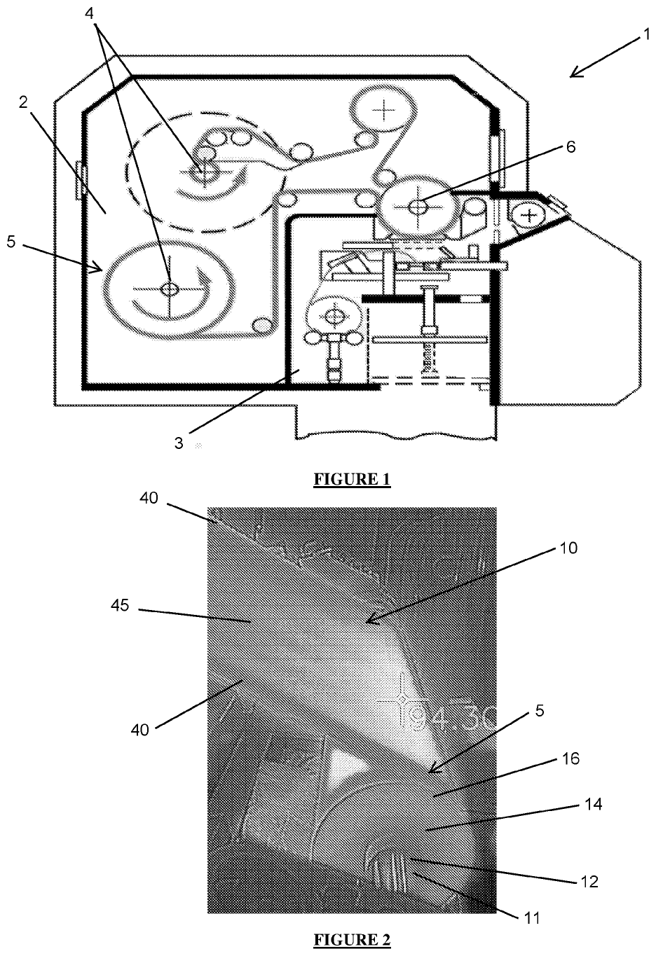

Referring to FIG. 2, there is illustrated an example of a roll 5 which is formed from a substrate 10. The substrate 10 is preferably linear and an approximate uniform width, with the substrate having a film applied to one or more of its sides. The core of the roll includes a cone or elongate tubular member 11 to which the substrate 10 is attached to allow for winding of the substrate 10 to form a roll 5. The elongate tubular member has a hollow core and allows mandrels or machine axes to be mounted therein which can form a friction fit or engaging fit to rotate the tubular member 11 and wind or unwind the substrate 10 to form said roll 5.

The centre 12 of the roll 5 includes the tubular member 11 and the first treated portion of the substrate 10. It will be appreciated that the centre 12, middle 14 and outer 14 portions of the roll will change with the addition or subtraction of substrate 10. For simplicity, the roll 5 referred to is a roll which has been treated with a deposition process which has applied at least one film or coating to the substrate 10. A cooling process or oxidation process may be initiated within 2 minutes to 60 minutes after deposition has been completed. Cooling processes and oxidation processes may be preferably completed within 5 minutes to 60 minutes if the system is required to be opened, or injection of atmosphere is required.

The different portions of the roll may have respective gradients of temperature. Generally, the outer portion of the roll 5 will have a temperature which is lower at the outer most layer and increase in temperature leading to the middle portion. Similarly, as the tubular member 11 is hollow, the temperature of the centre portion 12 of the roll 5 will generally be lower adjacent the tubular member 11, and increase in temperature towards the middle portion 14. In this case, the middle portion 14 of the roll 5 will have the highest temperature. As the temperatures throughout the roll are uneven, and the substrate is a porous substrate 10, oxidation may occur in undesired amounts and at undesired speeds.

As copper films oxidate at different rates for different temperatures, the exposure to oxygen must be limited during the cooling step relative to the heat of the substrate. This can reduce the visual change of the film applied to the substrate over time. For example, if the substrate is at a temperature of 150° C. the exposure to oxygen or ambient atmosphere will result in a colour change which may be ΔE of around 16 to 18 after 15 to 30 minutes, which is a substantial colour change discernible by human eyes. Further to the colour change, the oxides formed at the surface of the deposition may be different relative to oxides formed at a relatively lower temperature, or a relatively higher temperature.

The oxides formed at a temperature of around 50° C. are generally copper hydroxides, while oxides formed at a temperature of around 75° C. may include a higher concentration of copper oxide relative to the lower temperature of 50° C. The formation of different oxides can impart different characteristics, such as; functionality, bacterial inhibition, weight, reflectivity, durability, lustre, colour and surface roughness. To control these characteristics it may desirable to use the methods described herein to limit or enhance the oxidation rate of the substrate 10.

The brightness of the colour of the deposited material may be related to the level of oxidation, as the oxidation can impact the reflectivity of the film. Notably, oxidation may cause portions of the substrate to become transparent, which can reveal the lower substrate 10 depending on the thickness of the deposition applied. Further, the transparency or opacity of the film applied to the substrate may cause a tint, colouration, or other optical effect.

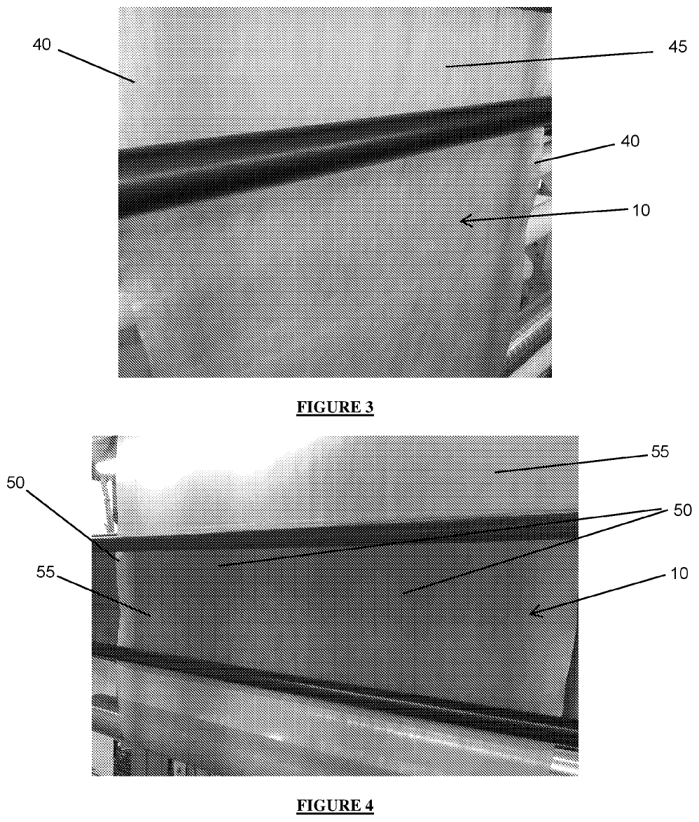

Uneven discolouration may also be formed with different local oxidation across the width of the substrate 10. An example of uneven oxidation across the width of the substrate is shown in FIG. 3, for example. As can be seen, the sides of the substrate are of a first colour and the middle is of a second colour. The colour change in these sections is primarily due to differences in temperature of the film, which causes oxides to form at the exposed surface of the film and propagate into the film. Different cooling rates of the film after deposition which may result in the film having different temperatures when exposed to the oxygen. The change in the rate of cooling will result in different regions of the film being oxidised differently, or oxidised forming undesired oxidation of the film applied thereto. It is preferred that after deposition, the temperature of the film is generally even, or be below of predetermined temperature such that undesired oxidation or uneven oxidation can be avoided.

In another embodiment, it may be desired to impart a gradient of oxidation to a substrate 10. As such the middle of the roll may be of a relatively higher temperature compared to the outer portion of the substrate 10 at the time of exposure to an oxidant.

It will be appreciated that the temperatures during the application of the film may exceed 200° C. In some processes, such as vapour deposition processes, the substrate 10 may be exposed to temperatures in the range of 200° C. to 350° C. The temperature may be related to the speed of the substrate 10, and the heat radiating from the boats of the system used to create a vapour to form the film on the substrate 10, in addition to the condensation of the metal vapour from the deposition process. The temperature of the film on the substrate may directly relate to the depth of oxidation observed in uncontrolled atmosphere. Generally, the higher the temperature of the substrate 10, the greater the depth of the oxidation in the film. Conversely, the lower the temperature of the substrate the thinner the oxide layer may be. It will be appreciated that there may be a lower temperature in which a minimum oxide layer forms at the surface of the film. For example, at temperatures of around 50° C. or less, an oxide layer formed at the surface of a copper film may be of a known thickness, or a minimum thickness for the film. Controlling the depth of the oxide layer may enhance properties of the copper deposition relatively below the oxide layer.

The substrate 10 may have particular use in personal protective equipment (PPE) and medical applications, such as; masks, gowns, curtains, bandages, etc. In another embodiment, the substrate 10 comprises a copper film deposited thereto, which may be used to prevent or limit the growth of bacteria, and may also be used to inhibit, kill or disrupt viruses which interact with the film. The film may hold a charge which may destroy or impact the envelope of a virus, interacting therewith. Different oxides may also impart a desired charge to the film surface which is exposed.

FTIR analysis results reveal a higher concentration of non-oxidised copper when the reflectivity is relatively higher. When the level of oxidation is increased the reflectivity decreases, which may alter the emissivity, reflectivity, colour and the infrared properties of the film.

### Process

One or more processes may be used to apply a film to the substrate. The methods may include a number of steps to apply the film, and/or to control the oxidation of the film. Oxidation of films can cause different properties to be imparted to the film, and may be useful for a number of applications.

In yet a further embodiment, a process for treating a substrate and controlling oxidation of a film applied thereto.

Step 1 (105): Applying a film to a substrate, the film comprising at least one metal. The metal may be any predetermined metal, such as aluminium, copper, zinc, gold, silver, titanium, chrome, nickel and oxides of at least one of the aforementioned.

The roll 5 may be loaded into the winding chamber of the system 1, the system 1 may then be closed and the pump down of internal gases started to begin the film deposition process of Step 1. The film applied to the substrate may be applied with a PVD or CVD process, or similar deposition process for step 1. Each of these processes are the preferred methods to apply a film to a substrate 10. A deposition chamber within the system may be the location where the deposition occurs. A winding chamber may be the portion of the system in which the roll is wound to and from the deposition chamber. The winding chamber and the deposition chamber may be of different pressures. Each chamber of the system may be of a predetermined pressure, and each chamber may have a different pressure relative to another chamber. It will be appreciated that one or more chambers within the system 1 has the same pressure.

Step 2 (110): Expose the substrate film to local atmosphere or controlled atmosphere for a predetermined period of time. Preferably, the exposure time of the substrate with film is related to the temperature of the substrate 10 or the roll 5 and may also be related to the external atmosphere and relative humidity. The exposure time to any oxidant is preferably limited to less than 5 minutes before a cooling process is started, unless the substrate 10 with the film is of an ideal temperature which can be exposed to an oxidant. Optionally, the exposure to atmosphere after deposition of a film is limited to less 10 minutes, or less than 9 minutes, 8 minutes, or less than 7 minutes, 6 minutes, or less than 5 minutes, 4 minutes, or less than 3 minutes, 2 minutes, or than 1 minute. The number of exposures to atmosphere may be 1 or more, before the roll reaches an ideal temperature. Using a cooling step can allow outer portions of the roll 5 and the sides of the roll 5 to be cooled evenly with the middle and core of the roll 5 and thereby allowing a more desirable and even oxidation to take place. As the roll 5 may be porous in some embodiments, the exposure to oxygen needs to be controlled to limit uneven oxidation and the level of oxidation. Alternatively, the exposure to oxygen can be increased to accelerate the oxidation if the substrate is at a temperature which allows for oxidation.

In another embodiment, after applying a metallic film to the substrate 10, the pressure within the system can be returned to an atmospheric pressure. Returning the system 1 to atmospheric pressure with the roll still contained therein may be done with a local atmosphere or a controlled atmosphere. The desired pressure range may be within the range of 80 kPa to 120 kPa for example, but is more preferably around 101 kPa. The seal for the system chamber can then be broken and the substrate may be exposed to a controlled time period of ambient atmosphere.

Step 3 (115): Reseal film application chamber or control local atmosphere after exposure to atmosphere. Optionally, opening the system and introducing oxygen may be undesired and the system may remain closed to cool within a chamber 2 of the system 1.

Step 4 (120): After at least partially repressurising the chambers with the introduction of atmosphere or a controlled gas, the atmosphere of the chambers may be increased to or withdrawn down to 10⁻² bar pump down pressure, or any other desired pressure in the range of 10⁻¹ to 10⁻³ bar. Although atmospheric pressure may also be used if desired for some applications. The internal pressure of the chambers of the system 1 may be any predetermined pressure, and the pressure may be controlled by the introduction of a predetermined gas. The predetermined gas may be a gas including oxygen, pure oxygen, an inert gas or nitrogen, for example. Other gases may be introduced to allow for a reaction to occur, or to allow for a desired thermal conductive effect.

Step 5 (125): Set cooling drum temperature to desired range. For example, the drum may be cooled to between −10° C. to −15° C., however cooling may instead be in the range of 5° C. to −40° C.

Alternatively, if it is desired that the substrate temperature is to be increased, the cooling drum may have a temperature which exceeds 0° C., and heating elements within the system may be activated. The heating elements may be evaporation boats which can be heated to allow for the evaporation of metals, such as a metal wire feeds. The desired temperature of the evaporation boats may emit thermal energy which can be used to heat the substrate 10, and the temperature of the evaporation boats may be increased or decreased as required to heat the substrate 10 in a desired manner. With the addition of wire feed to the evaporation boat, or proximal thereto, evaporation can occur to form a film onto a substrate 10. The evaporation boats may be heated to temperatures of between 20° C. to 300° C., and may be used to heat the substrate 10 as it is wound through the system 1, which may be used to more uniformly heat the substrate 10, or to encourage liquids to outgas from the substrate 10.

In a further embodiment, the substrate 10 may be heated by a heating process before and/or after being applied with a film. A heating chamber or heating room may be used to raise the temperature of the substrate before deposition and may be used to remove moisture from within the substrate before treatment. Heating processes may also be used to improve the bonding between the film and the substrate 10. It will be appreciated that a heating chamber or heating room may not be part of the system 1, and may be a separate heating chamber or heating room.

Optionally, Step 4 and Step 5 may be in any desired order.

Step 6 (130): Optionally activate plasma treatment system. The plasma treatment system may be used to apply a coating to the substrate 10 or a film thereon, or may be used to etch or activate the surface of the film deposited onto the substrate. The plasma treatment system may be used to inject a controlled plasma fluid, such as oxygen, nitrogen, or an inert gas, for example. Plasma treatments may be used to encourage an oxide to form or be used to apply a protective coating to the film on the substrate 10. Plasma treatment systems may optionally be adapted to apply a polymeric coating, protective coating, functional coating, or another predetermined coating to the substrate, and/or film.

Step 7 (135): wind substrate through system 1 at a speed of between 0.1 m/s to 10 m/s. more preferably, the speed in which the substrate 10 is processed through the system is at a rate of 0.3 m/s to 3 m/s. In a specific embodiment, the winding speed of the substrate 10 may be around 0.5 m/s.

In an alternate Step 7, the roll 5 may be cooled outside of the system 1 in a cooling system or cooling room. The cooling system may have a sealable chamber which can be used to prevent or limit the ingress of oxidants into the cooling system while the roll 5 is being cooled to a desired temperature. Atmosphere within the cooling system can be controlled such that the roll may be cooled within a desired atmosphere. Separate cooling systems may include injection of cooled fluids, or other fluids which can reduce the overall temperature of the roll while limiting the potential for undesired oxidation.

Step 8 (140): Optionally repeat Steps 2 to 7 a number of desired times. Repeating these steps may allow for a desired cooling and oxidation process to be performed. The exposure of the substrate may be limited during these steps, and thereby necessitating the additional undertaking of one or more of steps 2 to 7.

Step 9 (145): Optionally package the roll, or part thereof, to prevent exposure to atmosphere for a desired period of time. The exposure of the roll to atmosphere may be limited to reduce undesired oxidation, or exposure to humid environments. In addition, packaging the roll may allow for a volume of oxygen to be removed from the roll or local the roll by vacuuming the atmosphere, and/or injecting a predetermined atmosphere, such as an inert gas, nitrogen or a similar predetermined gas.

Optionally, a pre-treatment may be applied to the substrate 10. The pre-treatment may be a plasma treatment, a spray coating, a padding application, a cooling treatment, a heating treatment, or any other predetermined treatment.

It will be appreciated that instead of the above process being used to control oxidation of the roll, the roll may be extracted from the system 1, and inserted into a control chamber, bag, or vessel, which will limit the exposure to atmosphere and thereby limit the oxygen which may react with the film. The roll may be allowed to cool in ambient conditions or within a climate control room.

In yet a further process, the roll may be temporarily exposed to atmosphere and then a portion of said atmosphere removed to allow for cooling in the absence of a full atmosphere, and these steps may be repeated a number of times. In this way cooling can occur with limited exposure to oxygen. The flow of the atmosphere throughout the roll may allow for conduction of heat from the roll thereby cooling the roll 5.

The cooling process winding speed may be a speed of around 0.5 m/s, however other speeds may also be used to either reduce or enhance the oxidation of the film applied. The speeds may be in the range of 0.1 m/s to 10 m/s, with the lower processing speeds reducing the formation of oxides at the surface and the faster speeds assisting with the formation of oxides in the presence of oxygen.

Lower processing speeds may allow for greater heat transfer from the substrate to the cooling drum 6. It will also be appreciated that the heat transfer may also be increased or decreased by lowering or raising the temperature of the cooling drum 6, respectively. By reducing the temperature of the substrate, the potential for oxidation of the film may be reduced when the substrate is exposed to an oxidant.

Preferably, the reduction of the temperature of the substrate 10 is controlled to gradually reduce the temperature across the width of the substrate in the presence of a small volume of oxygen, such that the oxidation can occur more evenly across the width. These methods may be used to gradually expose the substrate to encourage oxidation as desired. In yet a further embodiment, the system 1 may be used to both apply a film to a substrate and subsequently cool the substrate 10.

At least one method herein may control the temperature of the substrate 10 or a portion thereof and may assist with allowing for a gradual reduction of temperature. The reduction of temperature may also be relatively more uniform across the width of the substate 10 with the use of the methods disclosed herein. These methods may also be used to uniformly heat a substrate before a controlled oxidation is imparted to the substrate 10.

In another embodiment, it may be desirable to increase the heat of the substrate 10 to encourage a uniform oxidation in the presence of oxygen, or preheat the substrate and subsequently expose said substrate 10 to oxygen. Increasing the heat of the substrate 10 and film thereon and exposing said film 10 to an oxidant may reduce the reflectivity of the film, which may be advantageous for some applications. While the reflectivity may be reduced, the antibacterial and/or viricidal properties may still be present.

Any heating or cooling of the substrate 10 is preferably controlled such that a desired oxidation can be imparted to the film of the substrate. Heating the substrate in the presence of an oxidant may be used to oxidise the film during heating. Preferably this heating may be done in a controlled manner to allow even heating or even cooling of the film to ensure even oxidation across the width and length of the substrate 10.

Alternatively, the substrate 10 could be heated within the coating chamber and then exposed to oxygen/atmosphere allowing the film to oxidise in a controlled manner.

The system 1 may be fitted with one or more cooling devices 6, which may be a series of cooling drums, or may be any other predetermined cooling system which reduces the temperature of the substrate 10 before exposure to an oxidant, or reduces the temperature during exposure to a controlled atmosphere.

Optionally, heating of the substrate 10 and subsequent exposure to an oxidant may be followed by a cooling step to encourage oxidation for a predetermined period only, or for a predetermined depth of penetration into the film.

Increasing the temperature with exposure to oxygen may also impart a desired colour to the film. One or more oxide types may be formed with temperature control during exposure to oxygen or ambient atmosphere. These oxides may be opaque, transparent, or semi-transparent. The opacity of the film may at least partially reveal one or more underlying coatings or layers of the substrate.

In yet a further embodiment, it is preferred that the film is oxidised fully, or oxidised such that there is at least 80% oxidation of the film, or at least 85% oxidation of the film, or at least 90% oxidation of the film, or at least 95% oxidation of the film, or at least 97% oxidation of the film, or at least 99% oxidation of the film. Oxidation of the film may be desirable as the emissivity of the film can be either increased or lowered for specific applications. For example, increasing the oxidation will increase the emissivity of the film, and thereby may reduce the infra-red reflective properties, and the ability for heat transfer may be increased. This may be of particular advantage for military applications, medical applications, fashion applications, and the like.

Referring to FIG. 5 there is illustrated an embodiment of a Fourier-transform infrared spectroscopy (FTIR) analysis. The analysis illustrates that with increasing temperature and exposure to atmosphere can cause reflectivity to be diminished, and substrate, or layers under the film, to be observed. This may have some benefit as the layers below the film may have one or more optical properties which may be desirable, while the film applied may have a desired functional property which can be exploited while also exposing the underlying layer or substrate 10.

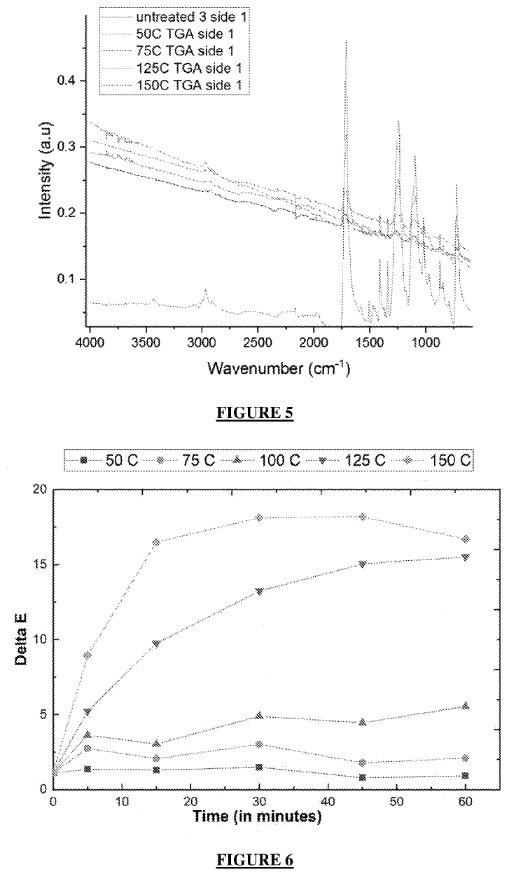

Referring to FIG. 6, there is illustrated a graph of ΔE values for different temperatures of a substrate and exposure to oxygen. As inherent by the nature of porous substrates, the pores within the substrate allow for the passage of fluids which comprise oxygen molecules, which can cause oxidation. As internal temperatures of a cooling roll are variable, the temperature in a localised region of the roll formed from a porous substrate may be different than other portions of the roll at a given time. As such, the controlled cooling of the roll, and the exposure to oxidising fluids is limited.

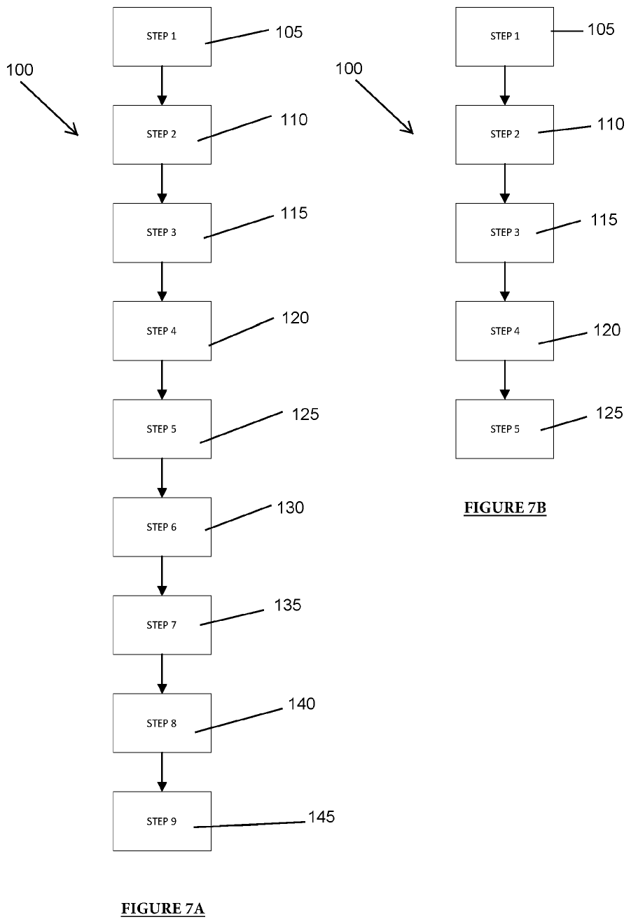

Turning to FIGS. 7A and 7B, there are shown embodiments of processes which may be used to cool the substrate 10. It will be appreciated that any steps herein may form part of the process of FIG. 7B and may be in any predetermined or desired order.

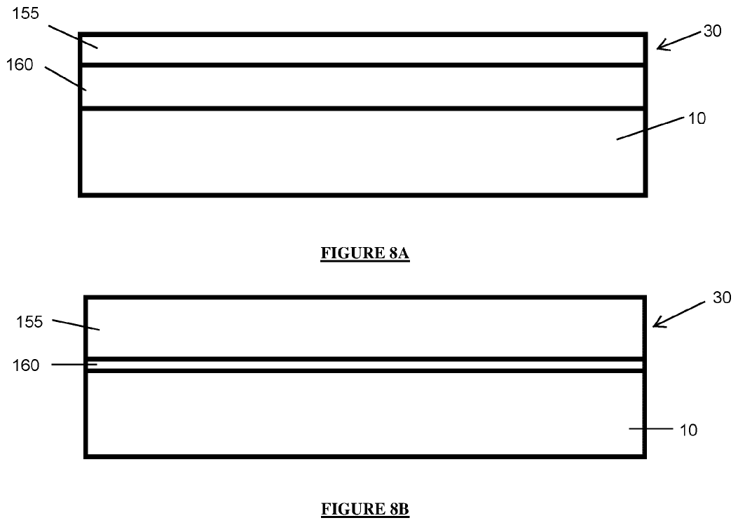

Referring to FIGS. 8A and 8B, there are shown embodiments of a substrate with a film applied thereto. The film is preferably a uniform thickness in these examples, however there may be some variation after oxidation has occurred. The depth of oxidation in FIG. 8A extends part way into the film, and the oxidation has been controlled to limit the depth of oxidation. Limiting the depth of the oxidation may reduce the emissivity of the film. Further, the reflectivity may be increased with limitation of the oxide thickness.

Turning to FIG. 8B there is illustrated an embodiment of another substrate with a film comprising an oxide layer which extends through more than 50% of the film thickness. The depth of the oxide layer will have impact on the emissivity of the film. The oxide layer on the film extending deeper into the substrate 10 may increase the emissivity of the film, and reduce the reflectivity. Further, the infrared reflectivity of the film may also be reduced with an increase of the oxide layer thickness.

After coating the substrate may have a reduction of between 5% to 20% for warp tensile strength, and between 5% to 25% for weft tensile strength. The reduction in the tensile strength may be relative to a sample which has not been provided with a deposition treatment.

In another embodiment, some substrates may increase in tensile strength with the addition of a film which has a controlled oxidation. The thickness of the oxide layer or the metal layer may increase the tensile strength of the substrate relative to an uncoated sample. The increase of the tensile strength may be in the range of 2% to 25%.

Oxidation does not occur within the vacuum chamber in the absence of oxygen, and as such, the controlled injection of atmosphere and the subsequent pumping down to remove the injected atmosphere can cause controlled cooling and/or oxidation. The controlled atmosphere may be any predetermined atmosphere, such as an inert gas, argon, nitrogen, hydrogen, oxygen or ambient atmosphere, for example. It will be appreciated that any desired coolant fluids may be used as controlled atmosphere. This is particularly relevant for porous materials which can allow oxygen to penetrate into the roll, in contrast with non-porous films such as PET films and the like which are commonly treated do not experience this oxygen exposure to cause oxidation as oxygen cannot penetrate into the roll to cause said oxidation. As such, the methods herein are a novel approach to solving these issues of porous films.

While the roll is within the chamber in vacuum the roll does not cool down quickly enough to reduce the temperature of the roll sufficiently. Notably, the roll 5 does not cool quickly due to the limited conductive and convective heat transfer within a vacuum, or near vacuum, environment. Some heat may be lost from the roll via radiation from the outside and sides of the roll 5, and some heat may also be lost through conducting through the core of the roll. However, a cooling process is required to bring the temperature of the substrate/film down below a desired temperature, for example around 50° C. for copper, such that the film does not unintentionally oxidise when the roll is removed from the chamber and exposed to an oxidant. This is one main reason for allowing for a rewinding process and the cooling processes described herein. It is preferred that the substrate 10 is wound over the cooling drum a number of times, and preferably the winding system of the system 1 is adapted to allow for winding both directions to achieve this cooling without injection of atmosphere or oxygen when undesired.

In another embodiment, the system 1 may be fitted with an in-line cooling device or a cooling chamber in which the roll with a film may be cooled. The roll 5 may be cooled as a whole, or the substrate 10 being wound onto the roll may be cooled. This can reduce the overall time that may be required to apply a film to substrate 10 as the cooling step may take place within the system during winding. In this case, the system 1 may be fitted with one or more cooling drums to cool the substrate 10 with a film. Alternatively, one or more cryogenic systems may be used to cool the substrate 10, or a local controlled atmosphere may be injected around the roll while in the system 1 to cool the roll and/or substrate 10. If atmosphere is injected into the system, the chamber with the atmosphere may be of a pressure which is closer to atmospheric pressure than the deposition chamber of the system.

Controlled atmosphere injected into the system may also be of a low temperature or cooled temperature to accelerate the cooling of the substrate 10 which forms the roll 5. It is preferred that the temperature of the roll at the time of exposure to an oxidant fluid is at a temperature to impart the desired level of oxidation. In some embodiments, the desired level of oxidation may be a minimum level of oxidation, or a maximum level of oxidation. The minimum level of oxidation may be the thinnest oxide layer which will form in ambient atmosphere, whereas the maximum level of oxidation may be an oxidation of the film to greater than 95% the films thickness.

In yet a further embodiment, the substrate 10 may be selectively heated in regions such as at the sides before oxidation, or in the middle without oxidation. This may impart a pattern or other visual effect to the film applied.

For example, heating a film to higher temperatures relative to deposition temperatures may also impart a desired colouration to the film, or may impart a desired functional property to the film. In the case of copper films, the colour imparted at higher temperatures may be a colour such as purple, blue, teal, red, orange, yellow or another colour which may be desired. It will be appreciated that these colours may only be produced in the presence of an oxidant.

While oxidation may be limited during the production process, a late-stage oxidation may be imparted to the film by increasing the temperature of the film in a local region to then allow for an oxidation reaction to occur. In one example, the film may be embossed or branded with a tool to impart a pattern, shape, colour, marker, or another visual difference to one or more regions of the film. Oxidation may be used for functional applications, such as reducing the infrared reflectivity of a material, or may be used for alterations to a surface. The surface topography may be roughened with an oxide formed at the surface, or may be used to impart an abrasion resistant or a protective layer to the film.

While the present method of application of a film to a substrate may be completed with sputtering methods, the preferred method of at least one embodiment may be the use of evaporative methods. The advantages for applying the film with evaporative methods may include; faster processing speeds relative to sputtering, more simple coating method, cheaper production costs, however use of evaporative methods generally increases the temperature of the substrate 10 to temperatures higher than that of sputtering methods. As such one or more methods herein may solve the problems inherently associated with evaporative methods, or with heating from sputtering methods which impart a temperature to the roll 5 exceeding a desired temperature threshold.

Further, film transfer methods as used in a number of conventional film application techniques are generally undesired as the film is adhered to the substrate with an adhesive, rather than a direct bonding to the substrate. Use of transfer films also generally block the pores or spaces between fibres such that the permeability is greatly reduced or eliminated. As such, the breathability of these substrates is dramatically decreased. Having a film applied with a PVD method allows for the breathability of the substrate to remain substantially the same as that before application of the film.

Although the invention has been described with reference to specific examples, it will be appreciated by those skilled in the art that the invention may be embodied in many other forms, in keeping with the broad principles and the spirit of the invention described herein.

The present invention and the described preferred embodiments specifically include at least one feature that is industrial applicable.

1. A substrate with a film comprising;
a porous substrate comprising one or more pores extending through the substrate;
a film applied to the porous substrate;
the film being a vapour deposited film formed from a metal vapour adhering to the surface of the substrate; and
wherein the film comprises a metal and a metal oxide.

2. The substrate as claimed in claim 1, wherein the metal oxide is at least 5 nm in thickness.

3. The substrate as claimed in claim 1, wherein the metal of the film is at least 5 nm in thickness.

4. The substrate as claimed in claim 1, wherein the tensile strength of the substrate is in the range of 75% to 95% of the tensile strength relative to a substrate without a film.

5. The substrate as claimed in claim 1, wherein the ΔE of the film is <3 after a period of more than 4 hours of the film being applied, relative to the colour of the film at the time of initial exposure to atmosphere external a film deposition system.

6. The substrate as claimed in claim 1, wherein the film is a copper film comprising a copper portion with a purity of greater than 95% and an oxide portion.

7. The substrate as claimed in claim 1, wherein the emissivity of the film is in the range of 0.1 to 0.8.

8. The substrate as claimed in claim 1, wherein the substrate has been exposed to a cooling process such that the ΔE of the film is not greater than 3 after a period of 4 hours, relative to the film at the time of removal from a film deposition system.

9. The substrate as claimed in claim 1, wherein the substrate is selected from the group of; a non-woven substrate, a membrane, a woven substrate, a fabric, and a textile.

10. The substrate as claimed in claim 1, wherein the substrate is cooled to a temperature in the range of 100° C. to 0° C. to control the metal oxide thickness.

11. The substrate as claimed in claim 1, wherein the thickness of the film is in the range of 5 nm to 500 nm, and comprises a metal layer and a metal oxide layer.

12. The substrate as claimed in claim 1, wherein the substrate has a first colour on a first side, and a second colour on a second side.

13. The substrate as claimed in claim 1, wherein the film has an emissivity of less than 0.15.

14. The substrate as claimed in claim 1, wherein the film has an emissivity of greater than 0.6.

15. The substrate as claimed in claim 1, wherein the metal is selected from the following group; aluminium, copper, zinc, gold, silver, titanium, chrome, and nickel.
